(19) United States
(12) Patent Application Publication
(10) Pub. No.: US 2026/0235677 A1
(43) Pub. Date: Aug. 13, 2026

(54) SEMICONDUCTOR DEVICE FOR PERFORMING TEST OPERATION OF THROUGH-SILICON VIAS

(71) Applicant: SAMSUNG ELECTRONICS CO., LTD., Suwon-si (KR)

(72) Inventors: Jiyoung LEE, Suwon-si (KR); Dongsu LEE, Suwon-si (KR)

(73) Assignee: SAMSUNG ELECTRONICS CO., LTD., Suwon-si (KR)

(21) Appl. No.: 19/443,494

(22) Filed: Jan. 8, 2026

(30) Foreign Application Priority Data
Feb. 7, 2025 (KR) 10-2025-0016168

(51) Int. Cl. G01R 31/3185; G11C 29/12; H10W 90/00; H10W 90/20

(52) U.S. Cl. CPC G01R 31/31855; G01R 31/318536; G01R 31/318541; G11C 29/1201; H10W 90/297; H10W 90/722

(57) ABSTRACT

A semiconductor device for performing a test operation of through-silicon vias (TSVs) are provided. The semiconductor device includes a memory die stack including a plurality of memory dies electrically connected through a plurality of TSVs and a system die comprising a system element and a controller for controlling the plurality of memory dies in accordance with an operation of the system element. The system die includes a boundary scan chain and a plurality of TSV input/output (IO) cells for testing connectivity of the plurality of TSVs. A TSV IO cell may include a first port connected to a corresponding one of the plurality of TSVs, a second port connected to the boundary scan chain, and a third port connected to the controller. The boundary scan chain detects whether the plurality of TSVs are normal or defective under the control by the controller.

### CROSS-REFERENCE TO RELATED APPLICATION

This application is based on and claims priority under 35 U.S.C. §119 to Korean Patent Application No. 10-2025-0016168, filed on February 7, 2025, in the Korean Intellectual Property Office, the disclosure of which is incorporated by reference herein in its entirety.

### BACKGROUND

The disclosure relates to a semiconductor device, and more particularly, to a semiconductor device for performing a test operation of through-silicon vias (TSVs).

Three-dimensional (3D) stack technology is being proposed as a solution to overcome scaling limitations. The 3D technology offers many advantages including high capacity, high bandwidth, low power, and small form-factor. A 3D semiconductor device uses a TSV method, which electrically connects chips to each other using silicon vias passing through the chips. A TSV provides communication connections between stacked chips from a vertical perspective and is an important element in 3D stacking. A system-on-chip (SOC) or an application processor (AP) included in electronic devices are evolving into complex forms, and clock frequencies thereof are also increasing. Additionally, an amount of data that electronic devices or systems can process is increasing. In line with this trend, providing high-speed, large-capacity memory systems is an important factor in the design competition for an SOC and other products.

An SOC that includes TSV-connected stacks need be tested for TSV input/output (IO) connection. When there are a large number of TSVs to test, the tester needs to have resources to test all of the TSVs, which is very expensive.

### SUMMARY

One or more example embodiments of the disclosure provide a semiconductor device that performs a test operation of through-silicon vias.

According to an aspect of an example embodiment of the disclosure, there is provided a semiconductor device including: a memory die stack comprising a plurality of memory dies, wherein the plurality of memory dies are electrically connected through a plurality of through-silicon vias (TSVs); and a system die comprising a system element and a controller configured to control the plurality of memory dies in accordance with an operation of the system element, wherein the system die comprises a boundary scan chain and a plurality of TSV input/output (IO) cells configured to test a connectivity of the plurality of TSVs, wherein a TSV IO cell of the plurality of TSV IO cells comprises: a first port connected to a corresponding TSV of the plurality of TSVs; a second port connected to the boundary scan chain; and a third port connected to the controller, and wherein the controller is configured to, in a test mode, couple the first port of the TSV IO cell to the second port of the TSV IO cell , and configured to, in a normal mode, couple the first port of the TSV IO cell to the third port of the TSV IO cell.

According to an aspect of an example embodiment of the disclosure, there is provided a semiconductor device including: a memory die stack comprising a plurality of memory dies and implemented as a high-bandwidth memory (HBM), wherein the plurality of memory dies are electrically connected through a plurality of through-silicon vias (TSVs); and a system die comprising a system element, a system (SOC) controller configured to control the system element, and an HBM controller configured to control the plurality of memory dies in accordance with an operation of the system element, wherein the system die comprises a boundary scan chain and a plurality of TSV input/output (IO) cells configured to test a connectivity of the plurality of TSVs, wherein a TSV IO cell of the plurality of TSV IO cells comprises: a first port connected to a corresponding TSV of the plurality of TSVs; a second port connected to the boundary scan chain; a third port connected to the SOC controller; and a fourth port connected to the HBM controller, and wherein the SOC controller is configured to, in a test mode, provide test input data to the HBM controller and couple the first port of the TSV IO cell to the second port of the TSV IO cell, and in a normal mode, couple the third port the TSV IO cell to the first port of the TSV IO cell.

According to an aspect of an example embodiment of the disclosure, there is provided a method of testing a connectivity of a plurality of through-silicon vias (TSVs) of a memory die stack connected to a system die of a semiconductor device, the method including: receiving, from a system (SOC) controller of the system die, an input/output (IO) mode signal for controlling an operation mode of TSV IO cells, wherein a TSV IO cell of the plurality of TSV IO cells comprises a first port connected to a corresponding TSV of the plurality of TSVs, a second port connected to a boundary scan chain, and a third port connected to the SOC controller; providing, by the TSV IO cell, data of the controller received by the third port to the corresponding TSV connected to the first port based on a first logic level of the IO mode signal; providing, by the TSV IO cell, data of the corresponding TSV connected to the first port to the third port based on a second logic level of the IO mode signal; receiving, by the TSV IO cell, a boundary scan mode signal from the SOC controller; coupling, by the SOC controller in a test mode, the first port to the second port based on the boundary scan mode signal; receiving, by the boundary scan chain, a scan enable signal and a scan clock signal from the SOC controller; latching, by the boundary scan chain comprising a plurality of scan circuits respectively connected to the plurality of TSV IO cells, data of the corresponding TSV provided by the first port and provided to the second port of a corresponding TSV IO cell of the plurality of TSV IO cells based on the scan enable signal; and sequentially outputting, by the boundary scan chain, data latched to the plurality of scan circuits based on the scan clock signal.

### BRIEF DESCRIPTION OF DRAWINGS

Example embodiments will be more clearly understood from the following detailed description taken in conjunction with the accompanying drawings in which:

FIGS. 1 and 2 are diagrams of a through-silicon via (TSV)-based semiconductor device according to one or more embodiments;

FIG. 3 is a diagram of TSVs of FIG. 1;

FIG. 4 is a diagram of the semiconductor device including TSV input/output (IO) cells and a boundary scan chain, according to one or more embodiments;

FIGS. 5, 6A, and 6B are diagrams of the TSV IO cell of FIG. 4 according to one or more embodiments;

FIG. 7 is a diagram of a semiconductor device including TSV IO cells and a boundary scan chain, according to one or more embodiments;

FIGS. 8, 9A and 9B are diagrams of the TSV IO cell in FIG. 7 according to one or more embodiments; and

FIG. 10 is a block diagram of a system to illustrate electronic equipment including a semiconductor device, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. In addition, one of ordinary skill would understand that aspects of some embodiments may be combined together or implemented alone.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

Through-silicon vias (TSVs) described herein are provided for interconnecting signals and/or power sources between stacked semiconductor chips. The stacked semiconductor chips may include a memory die stack and a system die. The memory die stack may include a plurality of memory die layers, and a system die may refer to a system layer including a system element such as, for example, a central processing unit (CPU), a graphics processing unit (GPU), a system-on-chip (SOC), or another related system element. In some embodiments, the system die may include a system element such as, for example, an application processor (AP), a natural processing unit (NPU), or the like.

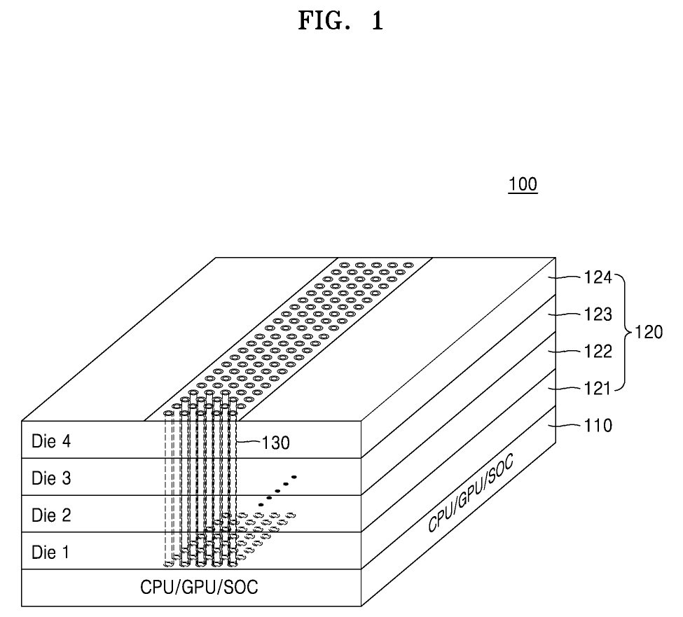

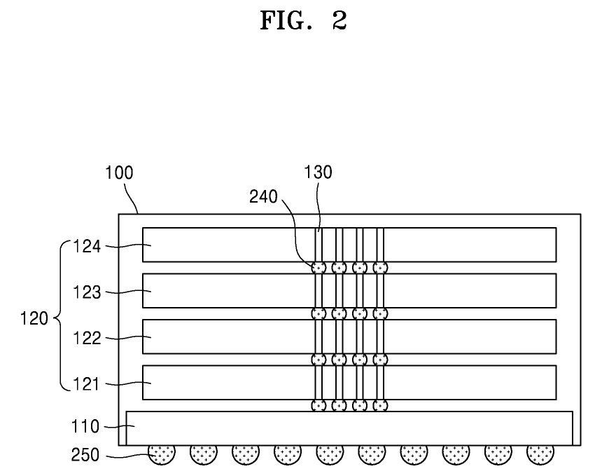

FIGS. 1 and 2 are diagrams of a TSV-based semiconductor device according to one or more embodiments. FIG. 2 is a cross-sectional view of the semiconductor device of FIG. 1. For ease of understanding, those described as upper surface/lower surface, an upper portion/lower portion, and above/below have been referred to with reference to a direction shown in the drawings. Accordingly, even the same surface may be referred to as an upper surface or a lower surface, according to the direction shown in the drawings.

Referring to FIGS. 1 and 2, a semiconductor device 100 may include multiple stacked dies. The semiconductor device 100 may perform functions including a memory device and a logic semiconductor device. For example, the memory device may include a high bandwidth memory (HBM) device, and the logic semiconductor device may include a CPU, a GPU, an NPU, an AP, an SOC, and the like.

The semiconductor device 100 may include a system die 110 and a memory die stack 120 stacked on the system die 110. The system die 110 may communicate with an external device, such as a host, through conductive means formed on an outer surface of the system die 110, such as solder balls 250. The memory die stack 120 may include first to fourth memory dies 121 to 124 and TSVs 130 passing through the first to fourth memory dies 121 to 124. The TSVs 130 may be electrodes that are made by drilling holes in a wafer by using laser chemical etching or drilling, such as deep reactive ion etching (DRIE), and then filling the holes using plating. The first to fourth memory dies 121 to 124 of the memory die stack 120 and the TSVs 130 may be electrically connected to each other by bumps 240 (or referred to as micro bumps). The bumps 240 may include conductive protrusions and may electrically connect the first to fourth memory dies 121 to 124 to the system die 110. Although the memory die stack 120 is described herein as including four memory dies, the embodiments of the disclosure are not limited thereto. Other numbers of memory dies may be included in the memory die stack 120, according to one or more embodiments.

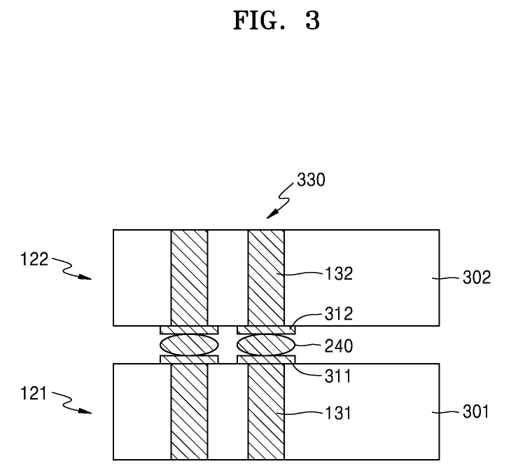

FIG. 3 is a diagram of the through-silicon vias TSVs in FIG. 1. FIG. 3 shows a first TSV 131 of the first memory die 121 and a second TSV 132 of the second memory die 122 in FIG. 1.

Referring to FIGS. 1 and 3, a first memory die substrate 301 and a second memory die substrate 302 stacked in a vertical direction are provided. The second memory die substrate 302 may be disposed on the first memory die substrate 301. The first TSV 131 passing through the first memory die substrate 301 may be formed, and a first electrode pad 311 may be formed on the first TSV 131. The first electrode pad 311 may be formed on one surface of the first memory die substrate 301 adjacent to the second memory die substrate 302. The second TSV 132 passing through the second memory die substrate 302 may be formed, and a second electrode pad 312 may be formed below the second TSV 132. The second electrode pad 312 may be formed on one surface of the second memory die substrate 302 adjacent to the first memory die substrate 301. The bump 240 may be formed between the first electrode pad 311 and the second electrode pad 312. The first memory die 121 may be connected to the second memory die 122 by an electrical connection structure 330 including the first and second TSVs 131 and 132, the first and second electrode pads 311 and 312, and the bump 240.

During a manufacturing process or use of the semiconductor device 100, a defect may occur in the electrical connection structure 330 including the first and second TSVs 131 and 132. For example, the defect may include a void defect caused by a failure to completely fill the TSV with a conductive material, a bump contact defect caused by bending of a semiconductor chip or movement of a bump material, or a crack defect of the TSV itself. When the defect occurs in the TSV, an error may occur in a signal transmission function through the TSV. Thus, it is necessary to verify TSV input/output (IO) connectivity with respect to the electrical connection structure 330. Hereinafter, test methods using TSV IO cells and a boundary scan chain for testing interconnection of TSVs are described.

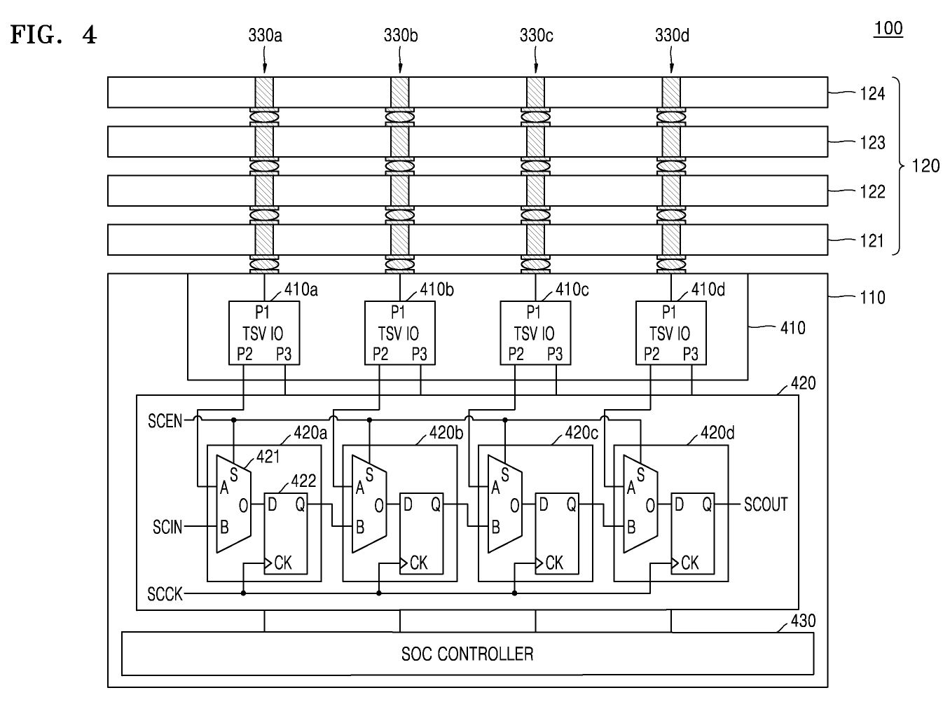

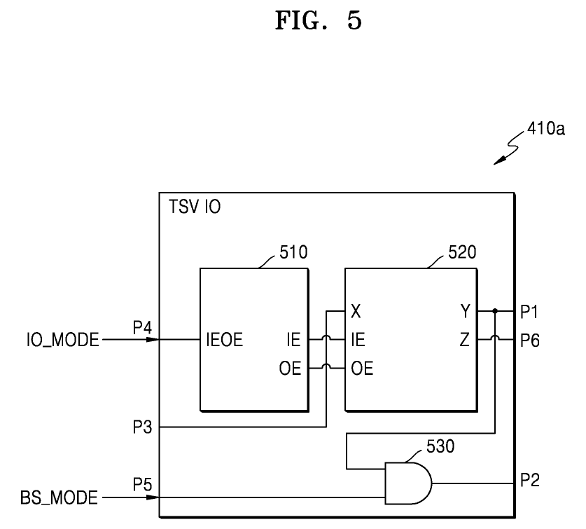

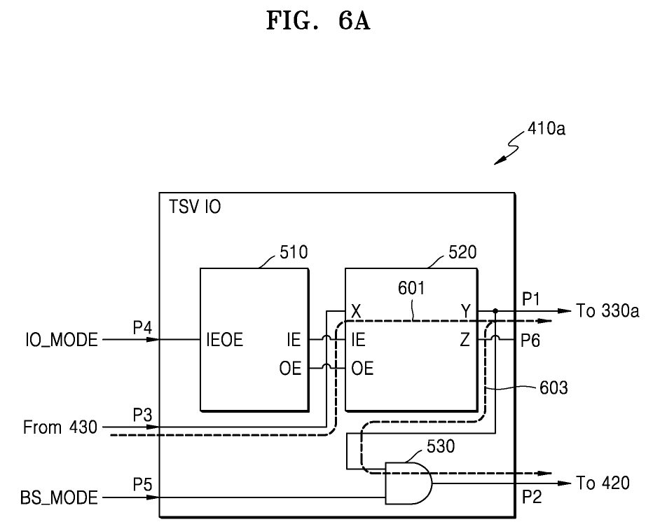

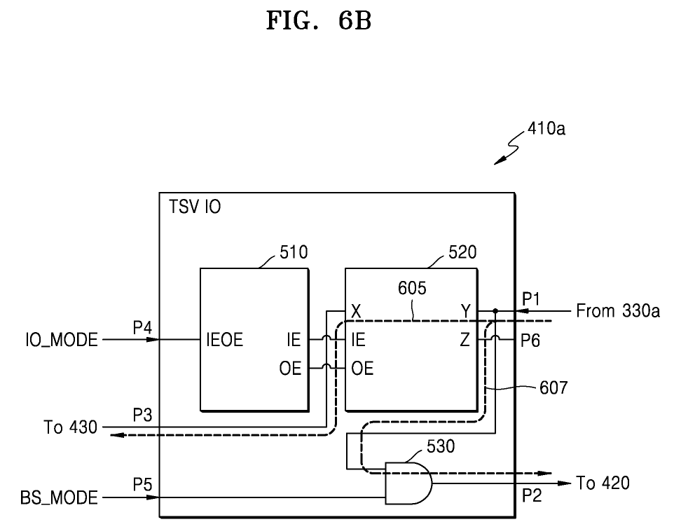

FIG. 4 is a diagram of the semiconductor device including the TSV IO cells and the boundary scan chain, according to one or more embodiments. FIGS. 5, 6A, and 6B are diagrams of a first TSV IO cell 410a in FIG. 4 according to one or more embodiments. A boundary scan chain 420 in FIG. 4 is described as testing some of the electrical connection structures 330 of the plurality of TSVs included in the semiconductor device 100, but is not limited thereto. The boundary scan chain 420 may test other numbers of electrical connection structures 330. In the following embodiments, the boundary scan chain 420 is described as testing the electrical connection structures 330. However, the boundary scan chain 420 may be understood as testing TSVs because the TSVs are included in electrical connection structures 330. For ease of description, the electrical connection structures 330 may be interchangeably referred to as TSVs 330. Subscripts (e.g., a of 330a and b of 330b) attached to the same reference numerals in different figures are intended to distinguish multiple components that have similar or identical functions.

Referring to FIGS. 1, 2, 3, and 4, the semiconductor device 100 may include the memory die stack 120, including the first to fourth memory dies 121 to 124 connected to each other by TSVs 330a, 330b, 330c, and 330d, above the system die 110. The system die 110 may include a TSV driver 410, the boundary scan chain 420, and a controller 430 (or referred to as an SOC controller), for testing the TSVs 330a, 330b, 330c, and 330d interconnecting the first to fourth memory dies 121 to 124 of the memory die stack 120. The controller 430 may control the first to fourth memory dies 121 to 124 in accordance with an operation of a system element included in the system die 110. The controller 430, which is a primary component that controls an operation of the semiconductor device 100, may execute an operating system and an application(s). The controller 430 may be a functional block configured to execute one or more machine-executable instructions or pieces of software, firmware, or a combination thereof. The controller 430 may be implemented using various circuit elements (or referred to as system elements) that perform calculation and other operations (e.g., memory operations) on the semiconductor device 100. The controller 430 may generate control signals that control an operation timing and/or a memory operation of the first to fourth memory dies 121 to 124 and may read data from and write data to the memory dies 122 to 124 by using the control signals. In addition, the controller 430 may be configured to control the TSV driver 410 and the boundary scan chain 420 by using the control signals.

The TSV driver 410 may include first to fourth TSV IO cells 410a, 410b, 410c, and 410d respectively connected to the TSVs 330a, 330b, 330c, and 330d of the first to fourth memory dies 121 to 124. The first to fourth TSV IO cells 410a, 410b, 410c, and 410d may be provided for scan testing for the TSVs 330a, 330b, 330c, and 330d of the first to fourth memory dies 121 to 124. The first TSV IO cell 410a may be connected to the TSVs 330a, the second TSV IO cell 410b may be connected to the TSVs 330b, the third TSV IO cell 410c may be connected to the TSVs 330c, and the fourth TSV IO cell 410d may be connected to the TSVs 330d.

Each of the first to fourth TSV IO cells 410a, 410b, 410c, and 410d may include first to third ports P1, P2, and P3. The first port P1 of each of the first to fourth TSV IO cells 410a, 410b, 410c, and 410d may be connected to a corresponding one of the TSVs 330a, 330b, 330c, and 330d, the second port P2 of each of the first to fourth TSV IO cells 410a, 410b, 410c, and 410d may be connected to the boundary scan chain 420, and the third port P3 of each of the first to fourth TSV IO cells 410a, 410b, 410c, and 410d may be connected to the controller 430. The first to fourth TSV IO cells 410a, 410b, 410c, and 410d may be arranged adjacent to the TSVs 330a, 330b, 330c, and 330d of the first to fourth memory dies 121 to 124 and may be included in a physical interface (hereinafter referred to as “PHY”) used for communication with the memory die stack 120. When the memory die stack 120 is implemented as an HBM, the first to fourth TSV IO cells 410a, 410b, 410c, and 410d may be arranged in an HBM PHY. Accordingly, the TSV driver 410 may be included in the HBM PHY in the system die 110. The HBM PHY may be provided to support the operating frequency, timing, driving, and detailed operating parameters of the HBM in accordance with the HBM specification so as to normally interoperate with the HBM, that is, the memory die stack 120.

In each of the first to fourth TSV IO cells 410a, 410b, 410c, and 410d, a path that couples (electrically connects) between the first port P1 connected to each of the TSVs 330a, 330b, 330c, and 330d and the second port P2 connected to the boundary scan chain 420 may be included in a test path for testing the TSVs 330a, 330b, 330c, and 330d when the semiconductor device 100 is in a test mode. In each of the first to fourth TSV IO cells 410a, 410b, 410c, and 410d, a path that couples between the first port P1 connected to each of the TSVs 330a, 330b, 330c, and 330d and the third port P3 connected to the controller 430 may be included in a signal path in which a normal operation (e.g., a write operation or a read operation) between the controller 430 and the first to fourth memory dies 121 to 124 is performed when the semiconductor device 100 is in a normal mode.

Referring to FIGS. 4 and 5, each of the first to fourth TSV IO cells 410a, 410b, 410c, and 410d may include the first port P1 connected to a corresponding one of of the TSVs 330a, 330b, 330c, and 330d, the second port P2 connected to the boundary scan chain 420, and the third port P3 connected to the controller 430, and may further include a fourth port P4, a fifth port P5, and a sixth port P6. The first to sixth ports P1 to P6 may be connected to a first logic circuit 510, a second logic circuit 520, and a third logic circuit 530. For convenience of description, the first TSV IO cell 410a connected to the TSVs 330a among the first to fourth TSV IO cells 410a, 410b, 410c, and 410d is described. The description of the first TSV IO cell 410a may be equally applied to the other TSV IO cells, that is, the second, third, and fourth TSV IO cells 410b, 410c, and 410d.

In the first TSV IO cell 410a of FIG. 5, the first logic circuit 510 may include a first signal terminal IEOE that receives an IO mode signal IO_MODE provided through the fourth port P4, a second signal terminal IE that outputs an input mode signal, and a third signal terminal OE that outputs an output mode signal. The first logic circuit 510 may selectively drive a logic level of the second signal terminal IE or the third signal terminal OE, according to a logic level of the first signal terminal IEOE. For example, when the IO mode signal IO_MODE having logic “0” is applied to the first signal terminal IEOE, the first logic circuit 510 may activate the second signal terminal IE as logic “1” and deactivate the third signal terminal OE as logic “0”. Conversely, when the IO mode signal IO_MODE having logic “1" is applied to the first signal terminal IEOE, the first logic circuit 510 may deactivate the second signal terminal IE as logic “0” and activate the third signal terminal OE as logic “1”. The first logic circuit 510 may set the first TSV IO cell 410a to operate in an input mode or an output mode, according to the IO mode signal IO_MODE received through the fourth port P4. The IO mode signal IO_MODE received by the fourth port P4 may be provided from the controller 430.

The second logic circuit 520 may include a first signal terminal X connected to the third port P3, a second signal terminal IE connected to the second signal terminal IE of the first logic circuit 510, a third signal terminal OE connected to the third signal terminal OE of the first logic circuit 510, a fourth signal terminal Y connected to the first port P1 of the first TSV IO cell 410a that receives a signal (or referred to as “data”) loaded on the TSVs 330a, and a fifth signal terminal Z connected to the sixth port P6 of the first TSV IO cell 410a. The third port P3 and the sixth port P6 may be designed to have connectivity with the first port P1, and signals loaded on the TSVs 330a received by the first port P1 may also be provided to the third port P3 and the sixth port P6. The sixth port P6 may be designed to output a signal loaded on the TSVs 330a to an outside of the semiconductor device 100. This enables the TSVs 330a to be monitored from the outside (e.g., test equipment).

In some embodiments, test data provided from the test equipment may be applied to the sixth port P6. The test data of the sixth port P6 may be loaded on the TSVs 330a connected to the first port P1 and may be provided to the boundary scan chain 420 through the second port P2. The boundary scan chain 420 may perform scan testing on the test data loaded on the TSVs 330a. This means that the test equipment may directly apply the test data to the TSVs 330a to test the TSVs 330a.

The third logic circuit 530 may be implemented as an end logic that performs an end logic operation on signals provided to the first port P1 and the fifth port P5. The fifth port P5 may receive a boundary scan mode signal BS_MODE provided from the controller 430 when the semiconductor device 100 is in the test mode. When the boundary scan mode signal BS_MODE of the fifth port P5 is activated as logic “1”, the third logic circuit 530 may output a signal loaded on the TSVs 330a connected to the first port P1 to the second port P2.

In the input mode, as shown in FIG. 6A (denoted by 601), the first TSV IO cell 410a may receive a signal provided from the controller 430 through the third port P3 and provide the signal to the TSVs 330a connected to the first port P1 through the first signal terminal X and the fourth signal terminal Y of the second logic circuit 520. In the output mode, as shown in FIG. 6B (denoted by 605), the first TSV IO cell 410a may provide the signal loaded on the TSVs 330a connected to the first port P1 to the controller 430 connected to the third port P3 through the fourth signal terminal Y and the first signal terminal X of the second logic circuit 520. In the test mode, as shown in FIG. 6A (denoted by 603), the first TSV IO cell 410a may provide the signal loaded on the TSVs 330a connected to the first port P1 in the input mode to the boundary scan chain 420 through the second port P2. In the test mode, as shown in FIG. 6B (denoted by 607), the first TSV IO cell 410a may provide the signal loaded on the TSVs 330a connected to the first port P1 in the output mode to the boundary scan chain 420 through the second port P2.

Referring back to FIG. 4, when in the input mode, the second TSV IO cell 410b may receive the signal provided from the controller 430 through the third port P3 and may provide the signal to the TSVs 330b connected to the first port P1. When in the output mode, the second TSV IO cell 410b may provide the signal loaded on the TSVs 330b connected to the first port P1 to the controller 430 connected to the third port P3. When in the test mode, the second TSV IO cell 410b may provide the signal loaded on the TSVs 330b connected to the first port P1 to the boundary scan chain 420 through the second port P2.

When in the input mode, the third TSV IO cell 410c may receive the signal provided from the controller 430 through the third port P3 and may provide the signal to the TSVs 330c connected to the first port P1. When in the output mode, the third TSV IO cell 410c may provide the signal loaded on the TSVs 330c connected to the first port P1 to the controller 430 connected to the third port P3. When in the test mode, the third TSV IO cell 410c may provide the signal loaded on the TSVs 330c connected to the first port P1 to the boundary scan chain 420 through the second port P2.

When in the input mode, the fourth TSV IO cell 410d may receive the signal provided from the controller 430 through the third port P3 and may provide the signal to the TSVs 330d connected to the first port P1. When in the output mode, the fourth TSV IO cell 410d may provide the signal loaded on the TSVs 330d connected to the first port P1 to the controller 430 connected to the third port P3. When in the test mode, the fourth TSV IO cell 410d may provide the signal loaded on the TSVs 330d connected to the first port P1 to the boundary scan chain 420 through the second port P2.

The boundary scan chain 420 may be connected to the first to fourth TSV IO cells 410a, 410b, 410c, and 410d, and may perform tests on the TSVs 330a, 330b,330c, and 330d, based on signals input/output to/from the first to fourth TSV IO cells 410a, 410b, 410c, and 410d. The boundary scan chain 420 may be referred to as boundary scan logic. The boundary scan chain 420 may include a first scan circuit 420a coupled to the first TSV IO cell 410a, a second scan circuit 420b coupled to the second TSV IO cell 410b, a third scan circuit 420c coupled to the third TSV IO cell 410c, and a fourth scan circuit 420d coupled to the fourth TSV IO cell 410d. Each of the first to fourth scan circuits 420a to 420d may include a multiplexer 421 and a scan logic latch 422.

For example, in the first scan circuit 420a connected to the first TSV IO cell 410a, the multiplexer 421 may include a selection signal terminal S, a first input signal terminal A, a second input signal terminal B, and an output signal terminal O. The selection signal terminal S may receive a scan enable signal SCEN, the first input signal terminal A may be connected to the second port P2 of the first TSV IO cell 410a, the second input signal terminal B may be connected to a scan input signal SCIN, and the output signal terminal O may be connected to an input signal terminal D of the scan logic latch 422. The scan logic latch 422 may latch data received by the input signal terminal D in response to a scan clock signal SCCK provided to a scan clock signal terminal CK and may output the data to an output signal terminal Q. An output signal of the output signal terminal Q of the scan logic latch 422 may be provided to the second scan circuit 420b and may be received by the second input signal terminal B of the multiplexer (such as 421) of the second scan circuit 420b. The scan enable signal SCEN, the scan input signal SCIN, and the scan clock signal SCCK may be provided from the controller 430 when the semiconductor device 100 is in the test mode.

In the second scan circuit 420b coupled to the second TSV IO cell 410b, the multiplexer (such as 421) may receive the scan enable signal SCEN through the selection signal terminal S, the first input signal terminal A may be connected to the second port P2 of the second TSV IO cell 410b, and the second input signal terminal B may be connected to the output signal terminal Q of the scan logic latch 422 of the first scan circuit 420a. The scan logic latch (such as 422) of the second TSV IO cell 410b may latch data received by the input signal terminal D in response to the scan clock signal SCCK provided to the scan clock signal terminal CK and may provide the data to the second input signal terminal B of the multiplexer (such as 421) of the third scan circuit 420c.

In the third scan circuit 420c connected to the third TSV IO cell 410c, the multiplexer (such as 421) may receive the scan enable signal SCEN through the selection signal terminal S, the first input signal terminal A may be connected to the second port P2 of the third TSV IO cell 410c, and the second input signal terminal B may be connected to the output signal terminal Q of the scan logic latch (such as 422) of the second scan circuit 420b. The scan logic latch (such as 422) of the third TSV IO cell 410c may latch data received by the input signal terminal D in response to the scan clock signal SCCK provided to the scan clock signal terminal CK and may provide the data to the second input signal terminal B of the multiplexer (such as 421) of the fourth scan circuit 420d.

In the fourth scan circuit 420d connected to the fourth TSV IO cell 410d, the multiplexer (such as 421) may receive the scan enable signal SCEN through the selection signal terminal S, the first input signal terminal A may be connected to the second port P2 of the fourth TSV IO cell 410d, and the second input signal terminal B may be connected to the output signal terminal Q of the scan logic latch (such as 422) of the third scan circuit 420c. The scan logic latch (such as 422) of the fourth TSV IO cell 410d may latch data received by the input signal terminal D in response to the scan clock signal SCCK provided to the scan clock signal terminal CK and may output the data as a scan output signal SCOUT. The scan output signal SCOUT may be provided to the controller 430.

In the boundary scan chain 420, when the scan enable signal SCEN is at a first logic level, for example, logic “0”, the multiplexer 421 of the first scan circuit 420a may output the output of the second port P2 of the first TSV IO cell 410a to the output signal terminal O. The multiplexer (such as 421) of the second scan circuit 420b may output the output of the second port P2 of the second TSV IO cell 410b to the output signal terminal O, the multiplexer (such as 421) of the third scan circuit 420c may output the output of the second port P2 from the third TSV IO cell 410c to the output signal terminal O, and the multiplexer (such as 421) of the fourth scan circuit 420d may output the output of the second port P2 of the fourth TSV IO cell 410d to the output signal terminal O.

The controller 430 may perform the memory operation on the memory dies 121 to 124 to control the TSVs 330a, 330b, 330c, and 330d to carry the same data, e.g., data “0”. Then, the controller 430 may control the second port P2 of each of the first to fourth TSV IO cells 410a to 410d to output the data “0” of the TSVs 330a, 330b, 330c, and 330d. The data “0” of each of the TSVs 330a, 330b, 330c, and 330d may be provided to the first input signal terminal A of the multiplexer 421 of each of the first to fourth scan circuits 420a to 420d.

For example, the controller 430 may provide the scan enable signal SCEN of logic “0” to the boundary scan chain 420. The multiplexer 421 of each of the first to fourth scan circuits 420a to 420d may select the data “0” input to the first input signal terminal A and may provide the data to the scan logic latch 422. Then, the scan logic latch 422 of each of the first to fourth scan circuits 420a to 420d may sequentially output the output data “0” of the multiplexer 421 as the scan output signal SCOUT in response to the scan clock signal SCCK. The scan output signal SCOUT may be provided to the controller 430. The controller 430 may continuously monitor whether the scan output signal SCOUT received in response to the scan clock signal SCCK is data “0-0-0-0”. When the scan output signal SCOUT is received in an order of data “0-0-0-0”, the controller 430 may determine that the TSVs 330a, 330b, 330c, and 330d are not defective. When the received data is not in the order of data “0-0-0-0”, for example, is in an order of “0-0-0-1”, the controller 430 may detect a stuck 1 in the data corresponding to a fourth rising edge of the scan clock signal SCCK and may determine that the data output from the fourth scan circuit 420d, that is, the TSVs 330d, is defective.

In some embodiments, the controller 430 may perform the memory operation on the memory dies 121 to 124 to control the TSVs 330a, 330b, 330c, and 330d to carry the same data, e.g., data “1”. Then, the controller 430 may control the second port P2 of each of the first to fourth TSV IO cells 410a to 410d to output the data “1” of the TSVs 330a, 330b, 330c, and 330d. The multiplexer 421 of each of the first to fourth scan circuits 420a to 420d may select the data “1” input to the first input signal terminal A in response to the scan enable signal SCEN of logic “0” and may provide the data to the scan logic latch 422. Then, the scan logic latch 422 of each of the first to fourth scan circuits 420a to 420d may sequentially output the output data “1” of the multiplexer 421 as the scan output signal SCOUT in response to the scan clock signal SCCK. The controller 430 may continuously monitor whether the scan output signal SCOUT received in response to the scan clock signal SCCK is data “1-1-1-1”. When the scan output signal SCOUT is received in an order of data “1-1-1-1”, the controller 430 may determine that the TSVs 330a, 330b,330c, and 330d are not defective. When the received data is not in the order of data “1-1-1-1”, for example, is in an order of “1-1-1-0”, the controller 430 may detect a stuck 0 in the data corresponding to the fourth rising edge of the scan clock signal SCCK and may determine that the data output from the fourth scan circuit 420d, that is, the TSVs 330d, is defective.

The controller 430 may provide the scan enable signal SCEN of logic “1” to the boundary scan chain 420. In the boundary scan chain 420, the multiplexer 421 of the first scan circuit 420a may output the scan input signal SCIN of the second input signal terminal B to the output signal terminal O, and the scan logic latch 422 may latch the scan input signal SCIN in response to the scan clock signal SCCK and may provide the same to the second scan circuit 420b. The multiplexer (such as 421) of the second scan circuit 420b may output the scan input signal SCIN received by the second input signal terminal B to the output signal terminal O, and the scan logic latch (such as 422) may latch the scan input signal SCIN in response to the scan clock signal SCCK and may provide the same to the third scan circuit 420c. The multiplexer (such as 421) of the third scan circuit 420c may output the scan input signal SCIN received by the second input signal terminal B to the output signal terminal O, and the scan logic latch (such as 422) may latch the scan input signal SCIN in response to the scan clock signal SCCK and may provide the same to the fourth scan circuit 420d. The multiplexer (such as 421) of the fourth scan circuit 420d may output the scan input signal SCIN received by the second input signal terminal B to the output signal terminal O, and the scan logic latch (such as 422) may latch the scan input signal SCIN in response to the scan clock signal SCCK and may output the same as the scan output signal SCOUT.

The controller 430 may receive the scan output signal SCOUT after providing the scan input signal SCIN to the boundary scan chain 420. The controller 430 may compare the scan input signal SCIN with the scan output signal SCOUT to verify a normal operation of the boundary scan chain 420, that is, verify a circuit operation of the boundary scan chain 420. After verifying the circuit operation of the boundary scan chain 420, the controller 430 may perform scan testing for the TSVs 330a, 330b,330c, and 330d by using the first to fourth TSV IO cells 410a, 410b, 410c, and 410d and the boundary scan chain 420.

As described above, as the controller 430 provides the same data pattern to the TSV driver 410 and the boundary scan chain 420 to perform scan testing for the TSVs 330a, 330b, 330c, and 330d, the controller 430 may easily and quickly detect whether the TSVs 330a, 330b, 330c, and 330d are normal or defective.

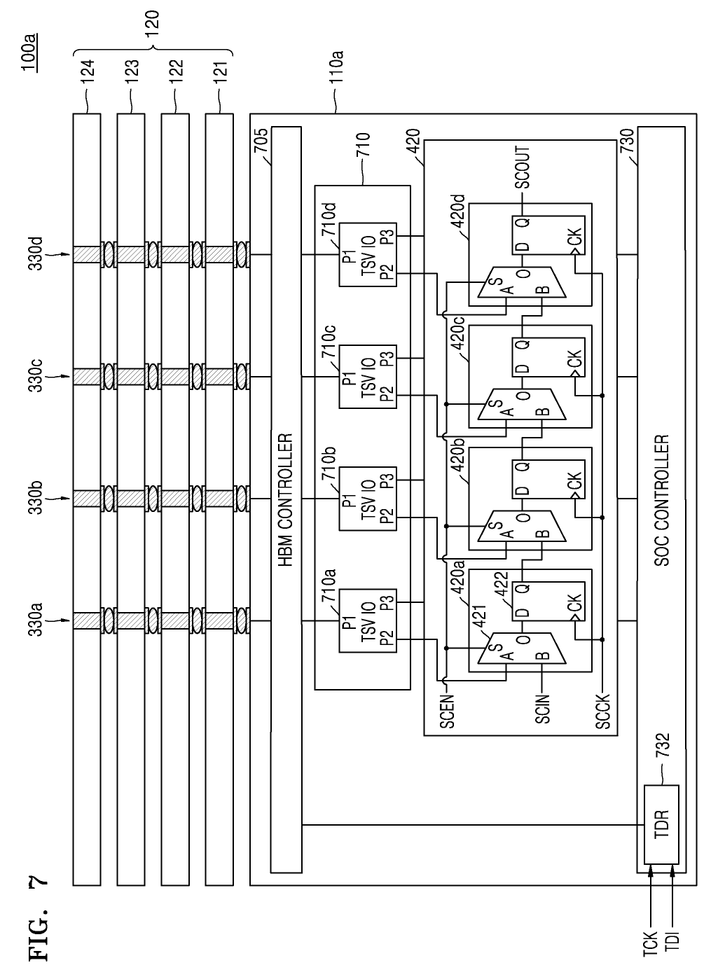

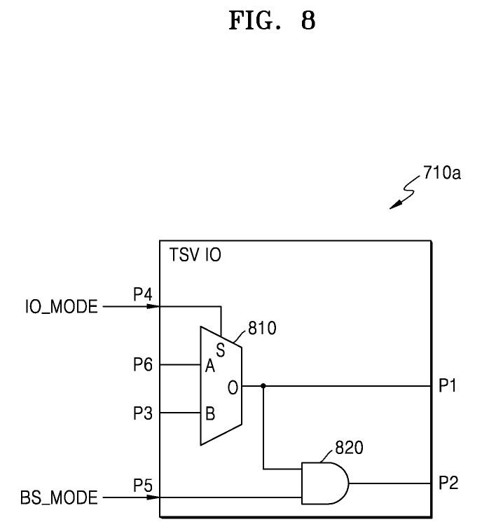

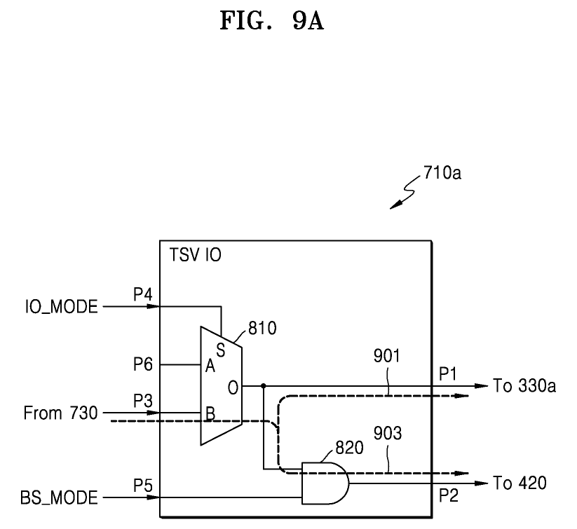

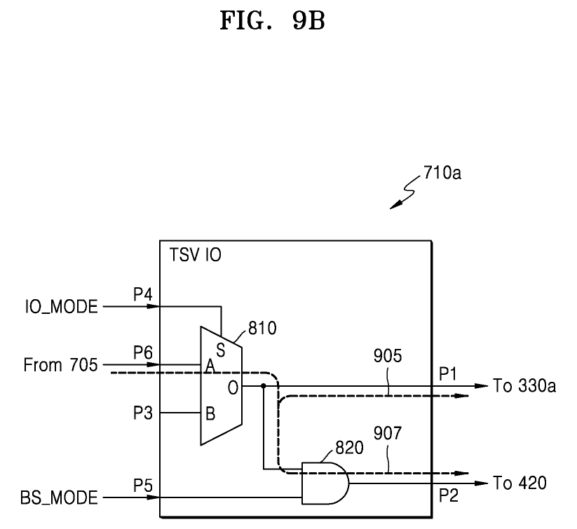

FIG. 7 is a diagram of a semiconductor device including TSV IO cells and a boundary scan chain, according to one or more embodiments. FIGS. 8, 9A, and 9B are diagrams of a first TSV IO cell 710a in FIG. 6 according to one or more embodiments. A semiconductor device 100a of FIG. 7 is different from the semiconductor device 100 of FIG. 4 in that the semiconductor device 100a may include an SOC controller 730, instead of the controller 430 of FIG. 4, and further may include an HBM controller 705. The SOC controller 730 is named to distinguish from the HBM controller 705. The HBM controller 730 may perform a HBM PHY function. Hereinafter, descriptions of the semiconductor device 100a that are substantially the same as those given with reference to FIG. 4 may be omitted.

Referring to FIG. 7, the semiconductor device 100a may include the memory die stack 120, including the first to fourth memory dies 121 to 124 connected by the TSVs 330a, 330b, 330c, and 330d, on a system die 110a, and the memory die stack 120 may be implemented as an HBM. The system die 110a may include the HBM controller 705, a TSV driver 710, the boundary scan chain 420, and the SOC controller 730, for testing the TSVs 330a, 330b, 330c, and 330d interconnecting the first to fourth memory dies 121 to 124 of the memory die stack 120.

The HBM controller 705 may support the operating frequency, timing, driving, and detailed operating parameters of the HBM in accordance with the HBM specification so as to normally interact with the memory die stack 120. The HBM controller 705 may be connected to the SOC controller 730 and may operate under the control by the SOC controller 730. The SOC controller 730 may control the first to fourth memory dies 121 to 124 of the memory die stack 120 through the HBM controller 705.

The SOC controller 730 may execute the operating system and application(s) of the semiconductor device 100a, like the controller 430 in FIG. 4. The SOC controller 730 may be configured to execute one or more machine-executable instructions or pieces of software, firmware, or a combination thereof and may be implemented using various circuit elements that perform computation and other operations (e.g., memory operations) in the semiconductor device 100a. The SOC controller 730 may generate control signals that control the operation timing and/or memory operation of the first to fourth memory dies 121 to 124 and may use the control signals to read data from and write data to the memory dies 122 to 124 through the HBM controller 705. In addition, the SOC controller 730 may be configured to control the TSV driver 710 and the boundary scan chain 420 through the HBM controller 705 by using the control signals.

The SOC controller 730 may include a test data register (TDR) 732 for testing the TSVs 330a, 330b, 330c, and 330d of the first to fourth memory dies 121 to 124. The TDR 732 may receive test input data TDI based on the test clock signal TCK provided from the test equipment outside the semiconductor device 100a. The test input data TDI may include an address for memory cells of the first to fourth memory dies 121 to 124. The TDR 732 may provide the received address to the HBM controller 705, and the HBM controller 705 may access the memory cells of the first to fourth memory dies 121 to 124 corresponding to the address. The signals associated with the address may then be loaded on the TSVs 330a, 330b, 330c, and 330d of the first to fourth memory dies 121 to 124.

The TSV driver 710 may include the first to fourth TSV IO cells 710a, 710b, 710c, and 710d connected to the TSVs 330a, 330b, 330c, and 330d of the first to fourth memory dies 121 to 124. The first to fourth TSV IO cells 710a, 710b, 710c, and 710d may be provided for scan testing for the TSVs 330a, 330b, 330c, and 330d of the first to fourth memory dies 121 to 124. The first TSV IO cell 710a may be coupled to the HBM controller 705 and the TSVs 330a, the second TSV IO cell 710b may be coupled to HBM controller 705 and the TSVs 330b, the third TSV IO cell 710c may be coupled to the HBM controller 705 and the TSVs 330c, and the fourth TSV IO cell 410d may be coupled to the HBM memory 705 and the TSVs 330d.

Each of the first to fourth TSV IO cells 710a, 710b, 710c, and 710d may include first to third ports P1, P2, and P3. The first port P1 of each of the first to fourth TSV IO cells 710a, 710b, 710c, and 710d may be connected to a corresponding one of the TSVs 330a, 330b, 330c, and 330d, the second port P2 of each of the first to fourth TSV IO cells 710a,710b, 710c, and 710d may be connected to the boundary scan chain 420, and the third port P3 of each of the first to fourth TSV IO cells 710a, 710b, 710c, and 710d may be connected to the SOC controller 730. The first to fourth TSV IO cells 710a, 710b, 710c, and 710d may be arranged adjacent to the HBM controller 705.

Referring to FIGS. 7 and 8, each of the first to fourth TSV IO cells 710a, 710b, 710c, and 710d may include the first port P1 connected to a corresponding one of the TSVs 330a, 330b, 330c, and 330d, the second port P2 connected to the boundary scan chain 420, and the third port P3 connected to the SOC controller 730, and may further include a fourth port P4, a fifth port P5, and a sixth port P6. The first to sixth ports P1 to P6 may be connected to a multiplexer 810 and a logic circuit 820. For convenience of description, the first TSV IO cell 710a connected to the TSVs 330a among the first to fourth TSV IO cells 710a, 710b, 710c, and 710d is described. The description of the first TSV IO cell 710a may be equally applied to the other TSV IO cells 710b,710c, and 710d.

In the first TSV IO cell 710a of FIG. 8, the multiplexer 810 may include the selection signal terminal S that receives the IO mode signal IO_MODE provided to the fourth port P4, the first input signal terminal A connected to the sixth port P6, the second input signal terminal B connected to the third port P3, and the output signal terminal O connected to the first port P1. The third port P3 may be connected to the SOC controller 730, and the sixth port P6 may be connected to the HBM controller 705.

The multiplexer 810 may operate in an input mode when the IO mode signal IO_MODE is logic “1” and may transfer data of the SOC controller 730 received by the second input signal terminal B through the third port P3 to the TSVs 330a connected to the first port P1. The multiplexer 810 may operate in an output mode when the IO mode signal IO_MODE is logic “0” and may transfer data of the HBM controller 705 received by the first input signal terminal A through the sixth port P6 to the TSVs 330a connected to the first port P1. The data of the HBM controller 705, including the signals associated with the address provided from the TDR 732, may be expected to have been transferred to the TSVs 330a.

The logic circuit 820 may be implemented as an end logic to perform an end logic operation on signals provided to the first port P1 and the fifth port P5. The fifth port P5 may receive the boundary scan mode signal BS_MODE provided from the SOC controller 730 when the semiconductor device 100a is in the test mode. When the boundary scan mode signal BS_MODE of the fifth port P5 is activated as logic “1”, the logic circuit 820 may output the signal loaded on the TSVs 330a connected to the first port P1 to the second port P2.

When the first TSV IO cell 710a is in the input mode, as shown in FIG. 9A (denoted by 901), the data provided from the SOC controller 730 connected to the third port P3 may be transferred to the first port P1. When the first TSV IO cell 710a is in the output mode, as shown in FIG. 9B (denoted by 905), the data provided from the HBM controller 705 connected to the sixth port P6 may be transferred to the first port P1. When the first TSV IO cell 710a is in the test mode, as shown in FIG. 9A (denoted by 903), the signal loaded on the TSVs 330a connected to the first port P1 in the input mode may be provided to the boundary scan chain 420 through the second port P2. When the first TSV IO cell 710a is in the test mode, as shown in FIG. 9B (denoted by 907), the signal loaded on the TSVs 330a connected to the first port P1 in the output mode may be provided to the boundary scan chain 420 through the second port P2.

Returning back to FIG. 7, when in the input mode, the second TSV IO cell 710b may receive the signal provided from the SOC controller 730 through the third port P3 and may provide the data to the TSVs 330b connected to the first port P1. When in the output mode, the second TSV IO cell 710b may transfer the data provided from the HBM controller 705 connected to the sixth port P6 to the first port P1. When in the test mode, the second TSV IO cell 710b may provide the signal loaded on the TSVs 330b connected to the first port P1 to the boundary scan chain 420 through the second port P2.

When in the input mode, the third TSV IO cell 710c may receive the signal provided from the SOC controller 730 through the third port P3 and may provide the signal to the TSVs 330c connected to the first port P1. When in the output mode, the third TSV IO cell 710c may transfer the data provided from the HBM controller 705 connected to the sixth port P6 to the first port P1. When in the test mode, the third TSV IO cell 710c may provide the signal loaded on the TSVs 330c connected to the first port P1 to the boundary scan chain 420 through the second port P2.

When in the input mode, the fourth TSV IO cell 710d may receive the signal provided from the SOC controller 730 through the third port P3 and may provide the signal to the TSVs 330d connected to the first port P1. When in the output mode, the fourth TSV IO cell 710d may transfer the data provided from the HBM controller 705 connected to the sixth port P6 to the first port P1. When in the test mode, the fourth TSV IO cell 710d may provide the signal loaded on the TSVs 330d connected to the first port P1 to the boundary scan chain 420 through the second port P2.

The boundary scan chain 420 may be connected to the first to fourth TSV IO cells 710a, 710b, 710c, and 710d, and may perform tests on the TSVs 330a, 330b,330c, and 330d based on signals input/output to/from the first to fourth TSV IO cells 710a,710b,710c, and 710d.

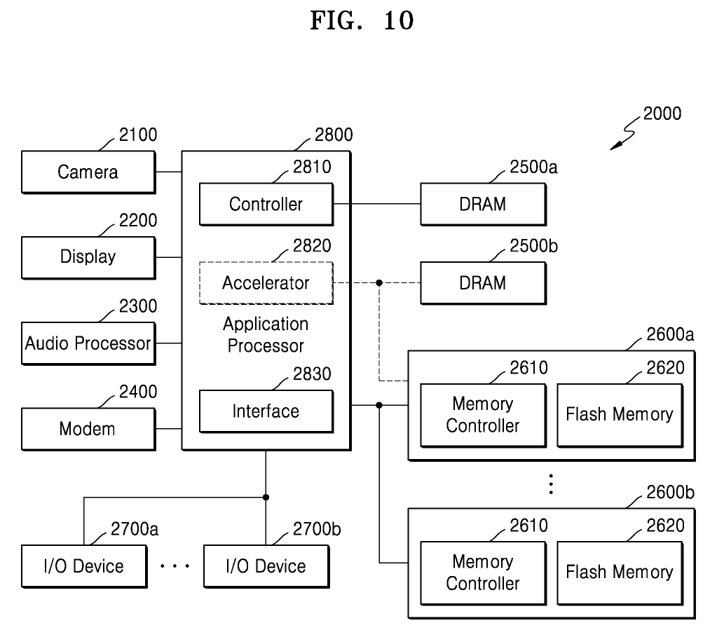

FIG. 10 is a block diagram of a system 2000 to illustrate electronic equipment including a semiconductor device, according to one or more embodiments.

Referring to FIG. 10, the system 2000 may include a camera 2100, a display 2200, an audio processor 2300, a modem 2400, dynamic random-access memories (DRAMs) 2500a and 2500b, flash memories 2600a and 2600b, I/O devices 2700a and 2700b, and an AP 2800. The system 2000 may be implemented as a laptop computer, a mobile phone, a smartphone, a tablet personal computer (PC), a wearable device, a healthcare device, or an Internet of Things (IoT) device. In addition, the system 2000 may be implemented as a server or a personal computer.

The camera 2100 may capture a still image or a moving image and may store or transmit the captured image/image data to the display 2200, under the control by a user. The audio processor 2300 may process audio data stored in the flash memories 2600a and 2600b or received through a network. The modem 2400 may modulate and transmit a signal for wired/wireless data transmission/reception and may demodulate the signal to recover the same to the original signal on the receiving side. The I/O devices 2700a and 2700b may include devices that provide digital input and/or output functionality, such as a universal serial bus (USB) or storage, digital cameras, secure digital (SD) cards, digital versatile discs (DVDs), network adapters, touch screens, and the like.

The AP 2800 may control the overall operation of the system 2000. The AP 2800 may include a controller block 2810, an accelerator block or accelerator chip 2820, and an interface block 2830. The AP 2800 may control the display 2200 such that data stored in the flash memories 2600a and 2600b is displayed on the display 2200. When a user input is received through the I/O devices 2700a and 2700b, the AP 2800 may perform a control operation corresponding to the user input. The AP 2800 may include an accelerator block that is a dedicated circuit for artificial intelligence (AI) data operation or may include the accelerator chip 2820 separately from the AP 2800. The accelerator block or accelerator chip 2820 may additionally be equipped with the DRAM 2500b. The accelerator chip 2820 may be a functional block that professionally performs a specific function of the AP 2800. The accelerator chip 2820 may include a GPU that is a functional block specialized in graphics data processing, an NPU that is a block specialized in AI computation and inference, and/or a data processing unit (DPU) that is a block specialized in data transfer.

The system 2000 may include the plurality of DRAMs 2500a and 2500b. The AP 2800 may control the DRAMs 2500a and 2500b by setting commands and mode registers (MRS) in accordance with joint electron device engineering council (JEDEC) standard specifications or may establish and communicate a DRAM interface protocol to use a company-specific function, such as low voltage/high speed/reliability, and a cyclic redundancy check (CRC)/error correction code (ECC) function. For example, the AP 2800 may communicate with the DRAM 2500a through an interface conforming to the JEDEC standard, such as LPDDR4 and LPDDR5, and the accelerator block or the accelerator chip 2820 may establish and communicate a new DRAM interface protocol to control the DRAM 2500b for accelerators having a higher bandwidth than the DRAM 2500a.

Although only the DRAMs 2500a and 2500b are illustrated in FIG. 10, any memory, such as phase-change random-access memory (PRAM), static RAM (SRAM), magneto-resistive RAM (MRAM), resistive RAM (RRAM), ferroelectric RAM (FRAM), or hybrid RAM, may be used as long as the bandwidth, reaction rate, and voltage conditions of the AP 2800 or the accelerator chip 2820 are satisfied. The DRAMs 2500a and 2500b have relatively smaller latency and bandwidth than the I/O devices 2700a and 2700b or the flash memories 2600a and 2600b. The DRAMs 2500a and 2500b may be initialized at a power-on time of the system 2000, and the operating system and application data may be loaded and used as a temporary storage for the operating system and the application data or as an execution space for various software code.

In the DRAMs 2500a and 2500b, addition, subtraction, multiplication, and/or division arithmetic operations and vector operations, address operations, or fast Fourier transform (FFT) operations may be performed. In addition, within the DRAMs 2500a and 2500b, a function may be performed for the performance used for the inference. Here, the inference may be performed in a deep learning algorithm using an artificial neural network. The deep learning algorithm may include a training step of learning a model through various data and an inference step of recognizing data with the learned model. In an embodiment, an image taken by a user through the camera 2100 may be signaled and stored in the DRAM 2500b, and the accelerator block or the accelerator chip 2820 may perform an AI data operation of recognizing data by using a function used for the inference and the data stored in the DRAM 2500b.

The system 2000 may include the plurality of storages or the plurality of flash memories 2600a and 2600b having a capacity greater than the DRAMs 2500a and 2500b. The accelerator block or the accelerator chip 2820 may perform the training step and the AI data operation using the flash memories 2600a and 2600b. In an embodiment, the flash memories 2600a and 2600b may include a memory controller 2610 and a flash memory device 2620 and may more efficiently perform the training step and the inference AI data operation performed by the AP 2800 and/or the accelerator chip 2820 by using an operation device provided in the memory controller 2610. The flash memories 2600a and 2600b may store a photograph taken through the camera 2100 or may store data transmitted to a data network. For example, augmented reality/virtual reality, high definition (HD), or ultra-high definition (UHD) content may be stored.

The components of the system 2000 may include the semiconductor devices described with reference to FIGS. 1 to 9B. The semiconductor devices may include a memory die stack that includes a plurality of memory dies and may be implemented with an HBM, a system (SOC) controller that controls a system element, and an HBM controller that controls the plurality of memory dies in accordance with the operation of the system element. The plurality of memory dies may be electrically connected to each other through the plurality TSVs, and the system die may include the boundary scan chain and the plurality of TSV IO cells for testing connectivity of the plurality of TSVs. Each of the plurality of TSV IO cells may include the first port connected to a corresponding one of the plurality of the TSVs, the second port connected to the boundary scan chain, the third port connected to the SOC controller, and the fourth port connected to the HBM controller. The SOC controller may provide test input data to the HBM controller when in the test mode, couple the first port to the second port of each of the plurality of TSV IO cells, and couple the third port to the first port of each of the plurality of TSV IO cells when in the normal mode. The boundary scan chain may receive the scan enable signal and the scan clock signal from the SOC controller, latch data of the TSV of the first port provided to the second port of each of the plurality of TSV IO cells by using the plurality of scan circuits respectively connected to the plurality of TSV IO cells based on the scan enable signal, and output, as the scan output signal, the latched data to the plurality of scan circuits based on the scan clock signal to provide the same to the SOC controller. The SOC controller may detect whether the plurality of TSVs are normal or defective based on the received scan output signal. Through such a semiconductor device, TSV testability may be increased and a defective TSV may be quickly detected. Such semiconductor devices may be usefully applied to high-speed communication devices and systems.

While the disclosure has been particularly shown and described with reference to example embodiments thereof, it will be understood that various changes in form and details may be made therein without departing from the spirit and scope of the following claims.

What is claimed is:

1. A semiconductor device comprising:
a memory die stack comprising a plurality of memory dies, wherein the plurality of memory dies are electrically connected through a plurality of through-silicon vias (TSVs); and
a system die comprising a system element and a controller configured to control the plurality of memory dies in accordance with an operation of the system element,
wherein the system die comprises a boundary scan chain and a plurality of TSV input/output (IO) cells configured to test a connectivity of the plurality of TSVs,
wherein a TSV IO cell of the plurality of TSV IO cells comprises:
a first port connected to a corresponding TSV of the plurality of TSVs;
a second port connected to the boundary scan chain; and
a third port connected to the controller, and
wherein the controller is configured to, in a test mode, couple the first port of the TSV IO cell to the second port of the TSV IO cell , and configured to, in a normal mode, couple the first port of the TSV IO cell to the third port of the TSV IO cell.

2. The semiconductor device of claim 1, wherein the TSV IO cell of the plurality of TSV IO cells further comprises a fourth port configured to receive an IO mode signal from the controller, and
wherein the TSV IO cell is configured to provide data of the controller received by the third port to the corresponding TSV connected to the first port, based on a first logic level of the IO mode signal, and provide data of the corresponding TSV connected to the first port to the third port, based on a second logic level of the IO mode signal.

3. The semiconductor device of claim 2, wherein the TSV IO cell of the plurality of TSV IO cells further comprises a fifth port configured to receive a boundary scan mode signal from the controller, and is configured to provide data loaded on the corresponding TSV, received by the first port to the second port based on an activation of the boundary scan mode signal.

4. The semiconductor device of claim 3, wherein the boundary scan chain comprises a plurality of scan circuits respectively connected to the plurality of TSV IO cells, respectively, and
wherein a scan circuit of the plurality of scan circuits comprises:
a multiplexer comprising a selection signal terminal configured to, in the test mode, receive a scan enable signal from the controller, a first input signal terminal connected to the second port of a corresponding TSV IO cell of the plurality of TSV IO cells, a second input signal terminal configured to receive a scan input signal from the controller, and an output signal terminal selectively connected to the first input signal terminal or the second input signal terminal based on the scan enable signal; and
a scan logic latch configured to, in the test mode, latch a signal output to the output signal terminal of the multiplexer based on a scan clock signal provided from the controller.

5. The semiconductor device of claim 4, wherein the boundary scan chain is configured to output a signal latched to a last scan circuit of the plurality of scan circuits as a scan output signal, to be provided to the controller.

6. The semiconductor device of claim 5, wherein the controller is configured to, in the test mode, cause data of a first pattern to be loaded onto the plurality of TSVs and monitor whether the received scan output signal is the data of the first pattern.

7. The semiconductor device of claim 5, wherein the controller is configured to, in the test mode, compare the scan input signal with the scan output signal received after providing the scan input signal.

8. A semiconductor device comprising:
a memory die stack comprising a plurality of memory dies and implemented as a high-bandwidth memory (HBM), wherein the plurality of memory dies are electrically connected through a plurality of through-silicon vias (TSVs); and
a system die comprising a system element, a system (SOC) controller configured to control the system element, and an HBM controller configured to control the plurality of memory dies in accordance with an operation of the system element,
wherein the system die comprises a boundary scan chain and a plurality of TSV input/output (IO) cells configured to test a connectivity of the plurality of TSVs,
wherein a TSV IO cell of the plurality of TSV IO cells comprises:
a first port connected to a corresponding TSV of the plurality of TSVs;
a second port connected to the boundary scan chain;
a third port connected to the SOC controller; and
a fourth port connected to the HBM controller, and
wherein the SOC controller is configured to, in a test mode, provide test input data to the HBM controller and couple the first port of the TSV IO cell to the second port of the TSV IO cell, and in a normal mode, couple the third port the TSV IO cell to the first port of the TSV IO cell.

9. The semiconductor device of claim 8, wherein the SOC controller is configured to receive the test input data based on a test clock signal provided from a test equipment outside the semiconductor device, and
wherein the test input data comprises an address for memory cells of the plurality of memory dies.

10. The semiconductor device of claim 9, wherein the TSV IO cell of the plurality of TSV IO cells comprises a fifth port configured to receive an IO mode signal from the SOC controller, and
wherein the TSV IO cell is configured to provide data of the SOC controller received by the third port to the corresponding TSV connected to the first port based on a first logic level of the IO mode signal, and provide data of the corresponding TSV connected to the first port to the third port based on a second logic level of the IO mode signal.

11. The semiconductor device of claim 10, wherein the TSV IO cell of the plurality of TSV IO cells further comprises a sixth port configured to receive a boundary scan mode signal from the SOC controller, and is configured to provide data loaded on the corresponding TSV of the first port to the second port based on an activation of the boundary scan mode signal.

12. The semiconductor device of claim 11, wherein the boundary scan chain comprises a plurality of scan circuits respectively connected to the plurality of TSV IO cells, respectively, and
wherein a scan circuit of the plurality of scan circuits comprises:
a multiplexer comprising a selection signal terminal configured to, in the test mode, receive a scan enable signal from the SOC controller , a first input signal terminal connected to the second port of a corresponding TSV IO cell of the plurality of TSV IO cells, a second input signal terminal configured to receive a scan input signal from the SOC controller, and an output signal terminal selectively connected to the first input signal terminal or the second input signal terminal based on the scan enable signal; and
a scan logic latch configured to, in the test mode, latch a signal output to the output signal terminal of the multiplexer based on a scan clock signal provided from the SOC controller.

13. The semiconductor device of claim 12, wherein the boundary scan chain is configured to output a signal latched to a last scan circuit of the plurality of scan circuits as a scan output signal, to be provided to the SOC controller.

14. The semiconductor device of claim 13, wherein the HBM controller is configured to, in the test mode, cause data associated with the address to be loaded on the plurality of TSVs, and the SOC controller is configured to monitor whether the received scan output signal is the data associated with the address.

15. The semiconductor device of claim 13, wherein the SOC controller is configured to, in the test mode, compare the scan input signal with the scan output signal received after providing the scan input signal.

16. A method of testing a connectivity of a plurality of through-silicon vias (TSVs) of a memory die stack connected to a system die of a semiconductor device, the method comprising:
receiving, from a system (SOC) controller of the system die, an input/output (IO) mode signal for controlling an operation mode of TSV IO cells, wherein a TSV IO cell of the plurality of TSV IO cells comprises a first port connected to a corresponding TSV of the plurality of TSVs, a second port connected to a boundary scan chain, and a third port connected to the SOC controller;
providing, by the TSV IO cell, data of the controller received by the third port to the corresponding TSV connected to the first port based on a first logic level of the IO mode signal;
providing, by the TSV IO cell, data of the corresponding TSV connected to the first port to the third port based on a second logic level of the IO mode signal;
receiving, by the TSV IO cell, a boundary scan mode signal from the SOC controller;
coupling, by the SOC controller in a test mode, the first port to the second port based on the boundary scan mode signal;
receiving, by the boundary scan chain, a scan enable signal and a scan clock signal from the SOC controller;
latching, by the boundary scan chain comprising a plurality of scan circuits respectively connected to the plurality of TSV IO cells, data of the corresponding TSV provided by the first port and provided to the second port of a corresponding TSV IO cell of the plurality of TSV IO cells based on the scan enable signal; and
sequentially outputting, by the boundary scan chain, data latched to the plurality of scan circuits based on the scan clock signal.

17. The method of claim 16, further comprising outputting, by the boundary scan chain, a signal latched to a last scan circuit of the plurality of scan circuits as a scan output signal to the SOC controller.

18. The method of claim 17, further comprising driving, by the SOC controller, the plurality of TSV IO cells to cause data having a first pattern to be loaded on the plurality of TSVs in the test mode, and monitoring, by the SOC controller, whether the received scan output signal is the data having the first pattern.

19. The method of claim 17, further comprising receiving, by the boundary scan chain in the test mode, a scan input signal from the SOC controller , and comparing, by the SOC controller, the received scan output signal with the scan input signal.

20. The method of claim 17, further comprising:
receiving, by the SOC controller, test input data indicating an address for memory cells of a plurality of memory dies from an external test equipment;
providing, by the SOC controller, the test input data to an HBM controller that controls the plurality of memory dies;
transferring, by the HBM controller, data associated with the address to the plurality of TSVs; and
monitoring, by the SOC controller, whether the received scan output signal is data associated with the address.
